(19) United States
(12) Patent Application Publication
(10) Pub. No.: US 2019/0271614 A1
(43) Pub. Date: Sep. 5, 2019

(54) High-Value Test Generation For Autonomous Vehicles

(71) Applicant: RightHook, Inc., San Jose, CA (US)

(72) Inventors: Warren Ahner, San Jose, CA (US); Jonathan Thomas Mullen, San Jose, CA (US)

(21) Appl. No.: 16/290,441

(22) Filed: Mar. 1, 2019

Related U.S. Application Data
(60) Provisional application No. 62/637,078, filed on Mar. 1, 2018.

(51) Int. Cl. G01M 17/00; G06F 17/50; G05D 1/00; B60R 21/02; B60W 30/095; G07C 5/08

(52) U.S. Cl. CPC G01M 17/00; G06F 17/5009; G05D 1/0088; B60R 2021/0065; B60W 30/095; G07C 5/0841; G05D 2201/0213; B60R 21/02

(57) ABSTRACT

A method for generating high-value test scenarios for autonomous vehicles. The method includes identifying multiple scenarios, each associated with a location on a road network. An injury value may be determined for each of the scenarios, and the scenarios and their associated injury values may be stored in a database. A desired location for testing an autonomous vehicle may be selected. At least one of the scenarios associated with the desired location and having an associated injury value that exceeds a predetermined threshold may be identified in the database. A virtual reality test environment may then be generated for the autonomous vehicle based on the at least one scenario. A corresponding system and computer program product are also disclosed and claimed herein.

### PRIORITY INFORMATION

This application claims priority to U.S. Application Ser. No. 62/637,078 filed on Mar. 1, 2018, entitled, “Method of Discovering High-Value Test Cases for Automated Driving.”

### BACKGROUND

### Field of the Invention

This invention relates to systems and methods for simulating and testing automated vehicle performance.

### BACKGROUND OF THE INVENTION

Autonomous vehicles are currently under test in various geographical regions. In each region, autonomous vehicles are tested on closed courses, on public roads, and in simulation under a variety of circumstances to “teach” such vehicles how to navigate and respond appropriately to their environment in all types of situations and conditions.

Virtual reality test environments are particularly advantageous as they are able to simulate traffic situations and conditions that would otherwise only be encountered by physically driving billions of miles across a countless number of locations and limitless circumstances. Virtual reality test environments may also be created to simulate actual road situations at various remote locations. In this manner, autonomous vehicle sensors and software may be trained to properly navigate a real-world driving environment specific to a certain geographical region before physically being put on the road at that location.

While the rate of automobile collisions at any particular location is very low, a location or intersection may be dangerous even absent a statistically significant number of collisions. Additionally, a statistically significant number of collisions at one location may suggest that certain features or combinations of features present at that location may also be dangerous if present at other locations. Certain circumstances or conditions may further increase the danger present at such a location.

Accordingly, what are needed are systems and methods to identify road locations, features and circumstances that pose a particular danger to automobile safety. Also what are needed are systems and methods to identify potentially dangerous locations and circumstances based on analogy to locations and circumstances that are known to be dangerous. Ideally, such systems and methods would be used for the purpose of scoping autonomous vehicle testing to high-value scenarios. Such systems and methods are disclosed and claimed herein.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is a high-level block diagram showing one example of a computing system in which a system and method in accordance with the invention may be implemented;

FIG. 2 is a flow chart of a method for identifying high-value test scenarios for autonomous vehicles in accordance with the present invention;

FIG. 3 is a flow chart of a method for generating high-value test scenarios for autonomous vehicles in accordance with the present invention;

FIG. 4 is a map view of one embodiment of a road network showing possible vehicle paths in accordance with embodiments of the invention;

FIG. 5 is a map view of another embodiment of a road network and associated vehicle paths in accordance with embodiments of the invention;

FIG. 6 is a set of matrices showing relationships between the vehicle paths depicted by FIG. 4; and

FIG. 7 is a set of matrices showing relationships between the vehicle paths depicted by FIG. 5.

### DETAILED DESCRIPTION

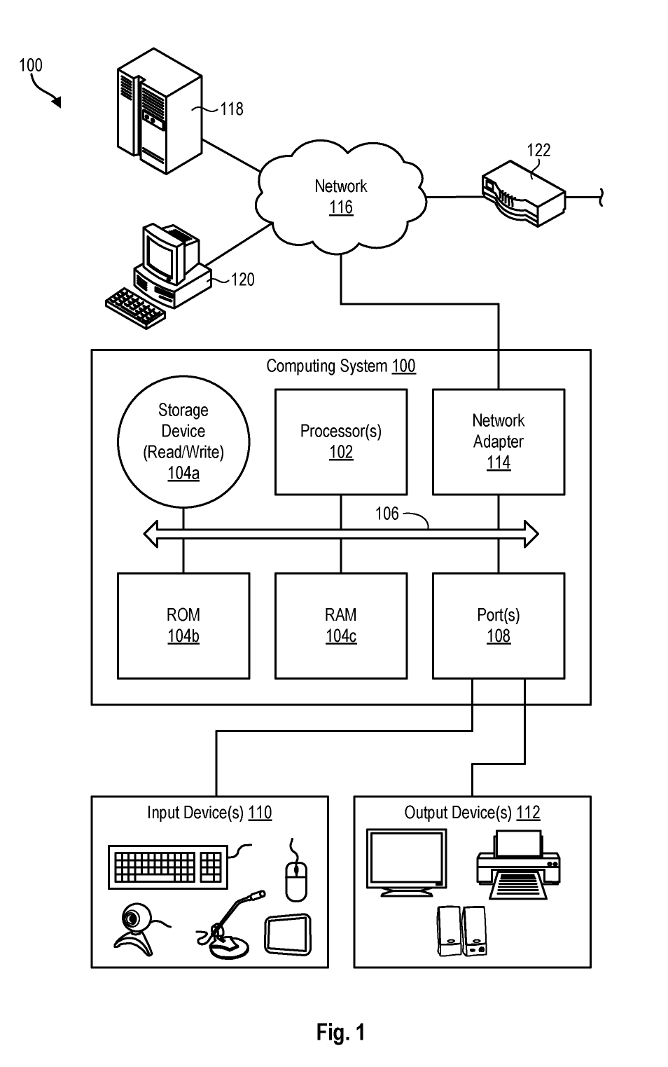

Referring to FIG. 1, one example of a computing system 100 is illustrated. The computing system 100 is presented to show one example of an environment where a system and method in accordance with the invention may be implemented. The computing system 100 may be embodied as a mobile device 100 such as a smart phone or tablet, a desktop computer, a workstation, a server, or the like. The computing system 100 is presented by way of example and is not intended to be limiting. Indeed, the systems and methods disclosed herein may be applicable to a wide variety of different computing systems in addition to the computing system 100 shown. The systems and methods disclosed herein may also potentially be distributed across multiple computing systems 100.

As shown, the computing system 100 includes at least one processor 102 and may include more than one processor 102. The processor 102 may be operably connected to a memory 104. The memory 104 may include one or more non-volatile storage devices such as hard drives 104a, solid state drives 104a, CD-ROM drives 104a, DVD-ROM drives 104a, tape drives 104a, or the like. The memory 104 may also include non-volatile memory such as a read-only memory 104b (e.g., ROM, EPROM, EEPROM, and/or Flash ROM) or volatile memory such as a random access memory 104c (RAM or operational memory). A bus 106, or plurality of buses 106, may interconnect the processor 102, memory devices 104, and other devices to enable data and/or instructions to pass therebetween.

To enable communication with external systems or devices, the computing system 100 may include one or more ports 108. Such ports 108 may be embodied as wired ports 108 (e.g., USB ports, serial ports, Firewire ports, SCSI ports, parallel ports, etc.) or wireless ports 108 (e.g., Bluetooth, IrDA, etc.). The ports 108 may enable communication with one or more input devices 110 (e.g., keyboards, mice, touchscreens, cameras, microphones, scanners, storage devices, etc.) and output devices 112 (e.g., displays, monitors, speakers, printers, storage devices, etc.). The ports 108 may also enable communication with other computing systems 100.

In certain embodiments, the computing system 100 includes a wired or wireless network adapter 114 to connect the computing system 100 to a network 116, such as a LAN, WAN, or the Internet. Such a network 116 may enable the computing system 100 to connect to one or more servers 118, workstations 120, personal computers 120, mobile computing devices, or other devices. The network 116 may also enable the computing system 100 to connect to another network by way of a router 122 or other device 122. Such a router 122 may allow the computing system 100 to communicate with servers, workstations, personal computers, or other devices located on different networks.

Embodiments of the invention may identify and generate high-value test scenarios and environments for autonomous vehicle simulation. Generally, high-value test scenarios are those that are particularly dangerous or difficult to navigate. While the rate of automobile collisions at any particular location is very low, a location or intersection may be dangerous even absent a statistically significant number of collisions. Additionally, a statistically significant number of collisions at one location may suggest that certain features or combinations of features present at that location may also be dangerous if present at other locations. Certain circumstances or conditions may further increase the danger associated with such a location.

Methods and systems in accordance with embodiments of the invention thus identify high-value test scenarios based on real and/or predicted data indicating a high expectation of injury at a certain location. Some embodiments further utilize a high-value scenario in one geographic location to identify and/or generate a similar high-value scenario in another geographic location. Embodiments of the present invention may also manipulate data to create virtual high-value scenarios having a maximum expectation of injury.

As used herein, the term “scenario” refers to information concerning both a static and dynamic driving environment. A scenario may include a location, initial conditions of a vehicle, and scenario features. The term “environment” refers to the three-dimensional geometry and road network topology of a real or fictitious place. The term “initial condition” refers to the positions, velocities, and other relevant physical states of autonomous vehicles and other actors when a scenario begins. The term “scenario features” or simply, “features”, refers to the set of measures calculated from information concerning the static and dynamic driving environment. These may include, for example, features calculated from information about the road network such as the location, time of day, weather, precipitation, traffic flow, configuration of road network users, vehicle speed, vehicle actions. and the like. The term “injury value” refers to a measure of the likelihood and severity of an injury. This measure is large if severe bodily harm is very likely, and small if severe bodily harm is unlikely.

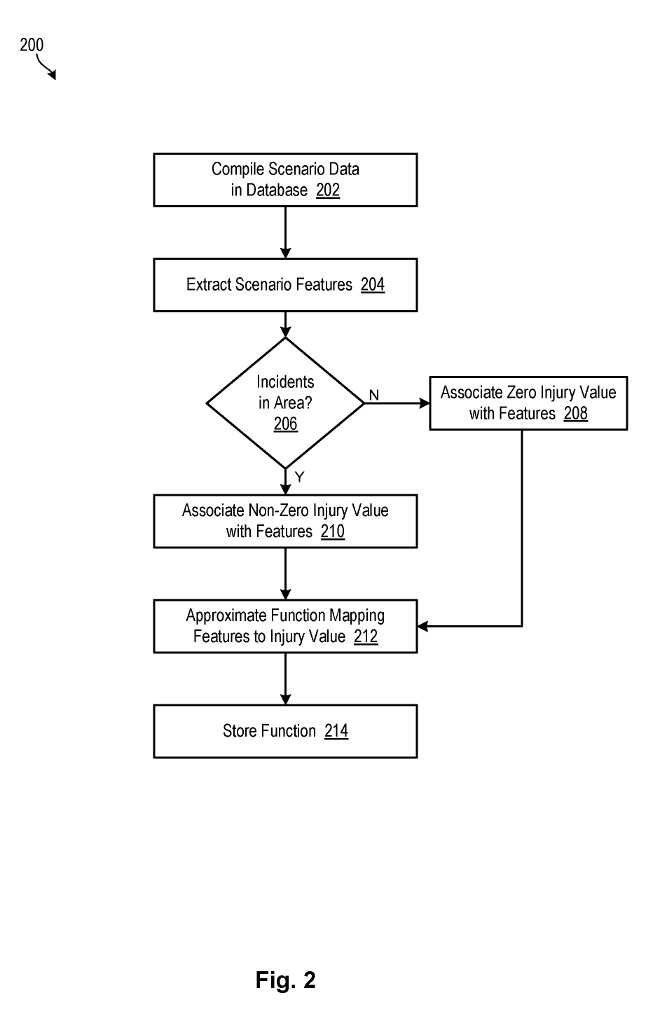

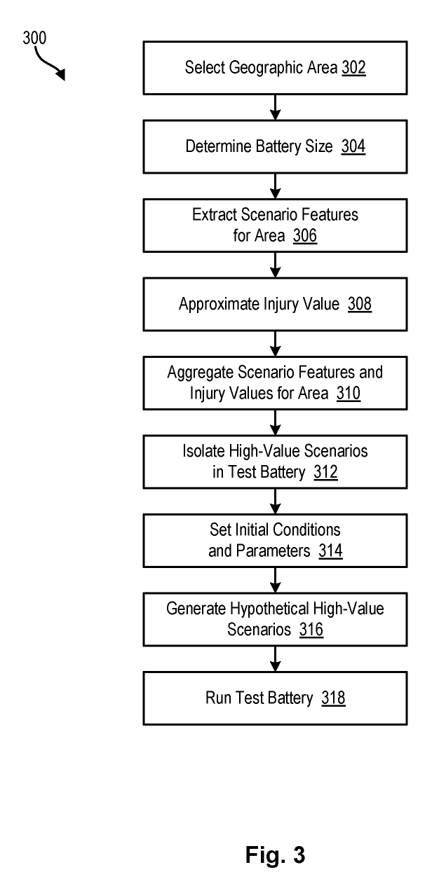

Generating high-value test scenarios or environments for autonomous vehicles in accordance with the invention may generally include a two-step process. First, as shown in FIG. 2, a method 200 may be used to build a function that maps scenario features to injury values. Next, as shown in FIG. 3, a method 300 may be used to select and/or create a set of scenarios that embodies scenario features that maximize injury values. This set of scenarios may be used as the testing set for autonomous vehicle simulations.

For example, as shown in FIG. 2, one embodiment of a method 200 for identifying high-value test scenarios for autonomous vehicles in accordance with the invention may include compiling 202 real-world scenario data in a database. This data may include static scenario features such as a geographic location, road geometry, road curvature, road grade, speed limit, presence of an intersection, and the like.

In certain embodiments, the data may further include dynamic scenario features, such as time of day, weather, precipitation, traffic flow (at various granularities), configuration of road network users, vehicle speeds, and other vehicle actions, such as driver aggressiveness or distraction. Scenario features may also include injury and/or fatality data derived from insurance reports for incidents that have occurred at the location, for example.

In certain embodiments, each scenario feature may be associated with a real numerical value. The numerical value may indicate the presence or absence of a condition (i.e., road curvature, blind spot, fatality), severity or ranking of a condition (i.e., road grade, degree of curvature, injury severity), recorded vehicle speed, or the like.

Road curvature, for example, may be a factor in vehicle crashes when a driver is distracted and runs off the road, for example, or when the road surface cannot support the friction necessary to negotiate the turn. Where road curvature computation is straightforward for a section of road leading up to a collision, a real number value may be assigned to the curvature and used in accordance with embodiments of the invention as described herein.

In some embodiments, the method 200 for identifying high-value test scenarios may extract 204 from the database scenario features that correspond to a desired geographic location. A geographic location may be particularly selected for autonomous vehicle simulation testing prior to rolling out public road testing in the same area, for example, or for any other reason known to those in the art.

In certain embodiments, the method 200 may then query 206 whether any vehicle accidents or other incidents have occurred in the selected geographic area. The response to the query 206 may determine an injury value associated with the scenario features. An injury value may be a real, non-negative value. If there have been no incidents in the area, for example, an injury value of zero may be associated 208 with the scenario features. If there has been at least one incident in the area, a non-zero injury value may be associated 210 with the scenario features.

The method 200 for identifying high-value test scenarios for autonomous vehicles in accordance with the invention may then approximate 212 a function mapping the scenario features to the injury value. As previously mentioned, scenario features may be given by [symbol] ∈ [symbol] ^{m}, and injury values may be given by [symbol] ∈ [symbol] >0. The injury value may be approximated by a function ƒ with m scenario features and n parameters, given as:

ƒ: [symbol] ^{m}× [symbol] ⁿ→ [symbol] .

In some embodiments, parameters may include numbers that must be learned or solved for to be able to compute the injury values from the scenario features. In certain embodiments, optimal parameters θₒₚₜ may be determined such that some cost representing the distance between a recorded or actual injury value [symbol] ᵢ and its estimate ƒ( [symbol] ,θ) is minimized. An example of one such function is:

$${θ}_{opt} = arg {min}_{θ} {( f ( {ℱ}_{i} , θ ) - {ℐ}_{i} )}^{2} + {θ}^{T} θ$$

The optimal parameter value derived from the function may be stored 214 in the database. In some embodiments, the function may also be stored 214 in the database. In one embodiment, as discussed in more detail below, the function may be accessed in the database and manipulated to create one or more hypothetical scenarios having desired features or injury values for autonomous vehicle simulation testing.

For example, in some embodiments, hypothetical scenarios not present in the database may be created to maximize the injury value [symbol] ᵢ. These hypothetical scenarios may correspond to one or more real or fictitious geographic locations. In one embodiment, a process for generating a high-value hypothetical scenario may sample the database for desired locations and compute an injury value for each using the function stored 214 in accordance with the method 200. Those scenarios with the highest injury values, or injury values above a predetermined threshold, for the desired locations may be separated out for autonomous vehicle simulation testing. In other embodiments, a similar process may be used to generate scenarios having desired or high-value initial conditions, or scenario features having corresponding feature values above a predetermined threshold, for example.

Referring now to FIG. 3, in certain embodiments, a method 300 for generating high-value test scenarios for autonomous vehicles in accordance with the invention may include selecting 302 a geographic area, which may be real or fictitious, and determining 304 an appropriate test battery size, or number of scenarios for testing in a given simulation or iteration.

For each geographic area selected 302, scenario features corresponding to the area may be extracted 306 from data compiled in the database. Features may include, for example, static data such as geographic location, road geometry, road curvature, road grade, speed limit, presence of an intersection, and/or the like. Features may also include injury and/or fatality data. In some embodiments, scenario features may include further include dynamic data such as time of day, weather, traffic flow (at various granularities), vehicle speeds, and/or other vehicle actions, such as driver aggressiveness or distraction.

Values for scenario features and parameters may be used in connection with a derived function (as shown in FIG. 2) to approximate 308 injury values for locations within the selected geographic area. These scenario features, parameters, and injury values may be aggregated for their associated geographic areas. In this manner, geographic areas and scenarios associated with particularly high scenario feature values, parameter values, and/or injury values may be easily identified as high-value for purposes of autonomous vehicle testing simulation.

The high-value areas or scenarios may then be isolated 312 for inclusion in one or more test batteries for autonomous vehicle simulation testing. In certain embodiments, an optimal mix of high-value scenario features and injury values may be determined for inclusion in a particular test battery. Initial conditions corresponding to such high-value scenario features and injury values may be sampled and used to set 314 similar or identical initial conditions for hypothetical high-value scenarios generated in accordance with embodiments of the invention. Parameters corresponding to the initial conditions may also be sampled and used to set 314 similar or identical parameters for high-value scenarios generated 316 in accordance with embodiments of the invention.

A test battery of simulations may then be run 318 for an autonomous vehicle, which simulations may include real-world scenarios, hypothetical scenarios, or a combination of both. In certain embodiments, the test battery may be run 318 by systems such as those disclosed by U.S. Pat. App. No. 62/639,896.

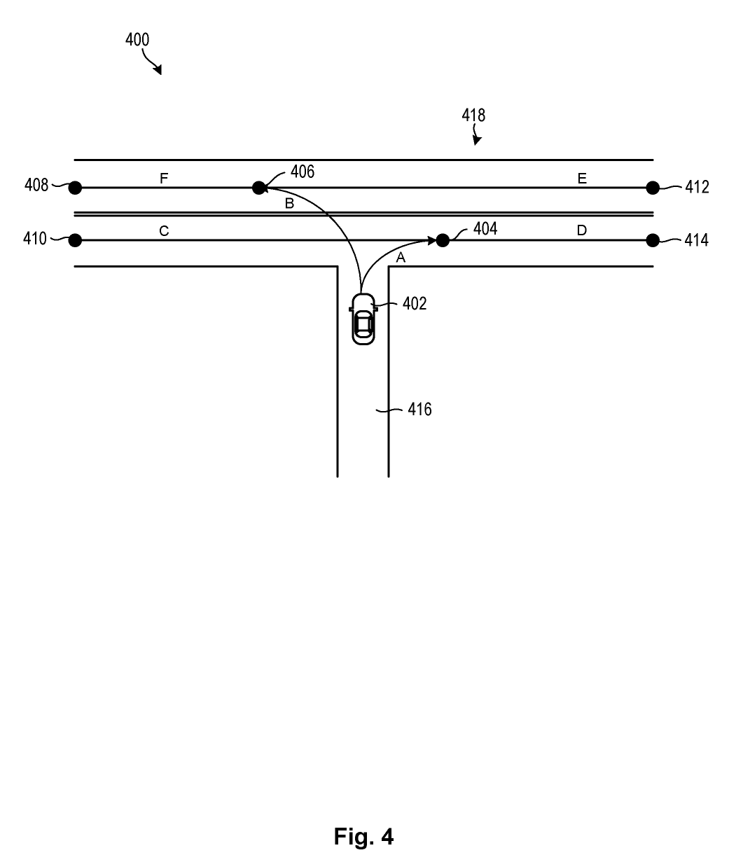

Referring now to FIG. 4, a real-world road network 400 may be located in any geographic area, and may include at least one road 416, 418 that may be navigated by one or more vehicles 402. Each vehicle 402 may take one or more pathways A-F with respect to the roads 416, 418 of the road network 400.

For example, as shown, an autonomous vehicle 402 may navigate a one-way road 416 that dead-ends into a two-way road 418. At the intersection of the roads 416, 418, the vehicle 402 may make a right hand turn from the one-way road 416 onto the two-way road 418, along pathway A. Alternatively, the vehicle 402 may make a left hand turn from the one-way road 416 to the two-way road 418, along pathway B.

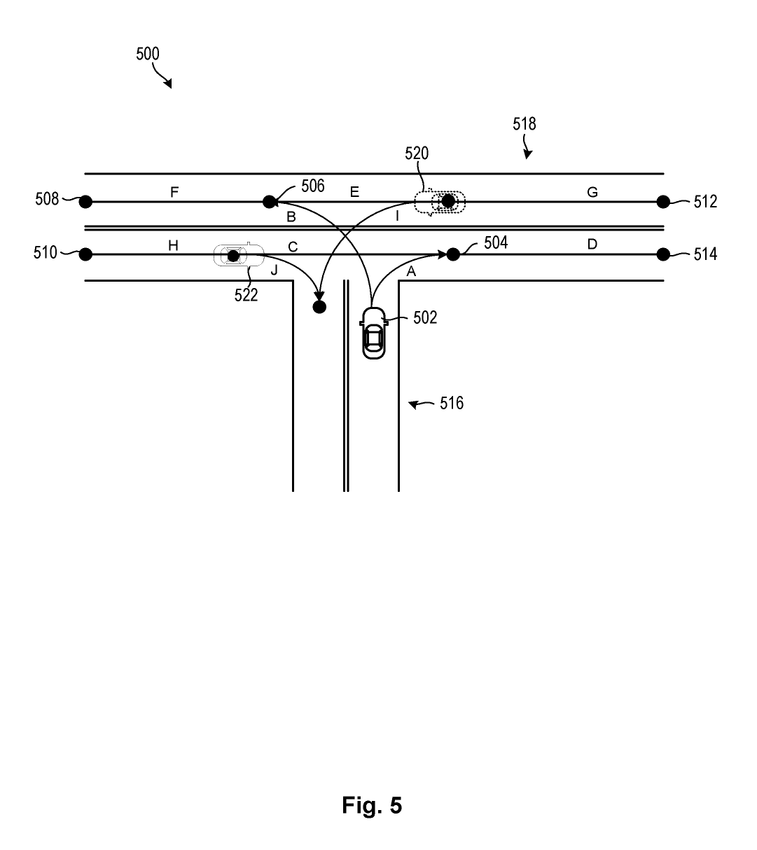

Referring now to FIG. 5, another vehicle 502 may navigate another real-world road network 500 in another geographic area. This road network 500 may include a first two-way road 516 that dead-ends into a second two-way road 518. At the intersection of the two-way roads 516, 518 the vehicle 502 may make a right hand turn from the first two-way road 516 onto the second two-way road 518, along pathway A. Alternatively, the vehicle 502 may make a left hand turn from the first two-way road 416 onto the second two-way road 518, along pathway B.

Further, a second vehicle 520 traversing the second two-way road 518 in one direction may opt to continue straight on the road 518 along pathway segments E and F, or may make a left hand turn onto the first two-way road 516, along pathway I. Similarly, a third vehicle 522 traversing the second two-way road 518 in an opposite direction may continue straight on the road 518 along pathway segments C and D, or may make a right hand turn onto the first two-way road 516 along pathway J.

In many cases, the nature of connections and crossings in the road network 400, 500 itself may make certain areas or locations difficult or dangerous. It is reasonable to expect that if one road network 400, 500 is dangerous, another road network 400, 500 like it may also be dangerous. To this end, certain features of a road network 400, 500 may be identified and used to establish similarities between it and another road network 400, 500, such that one road network 400 in one geographic location may be analogized to another road network 500 in another geographic location, real or hypothetical.

For any particular road network 400, 500, such as those shown in FIGS. 4 and 5, certain embodiments of methods and systems in accordance with the invention may generate matrices to identify scenario features based on road network topology. Such matrices may then be used to establish similarities between two or more road networks 400, regardless of their geographic location.

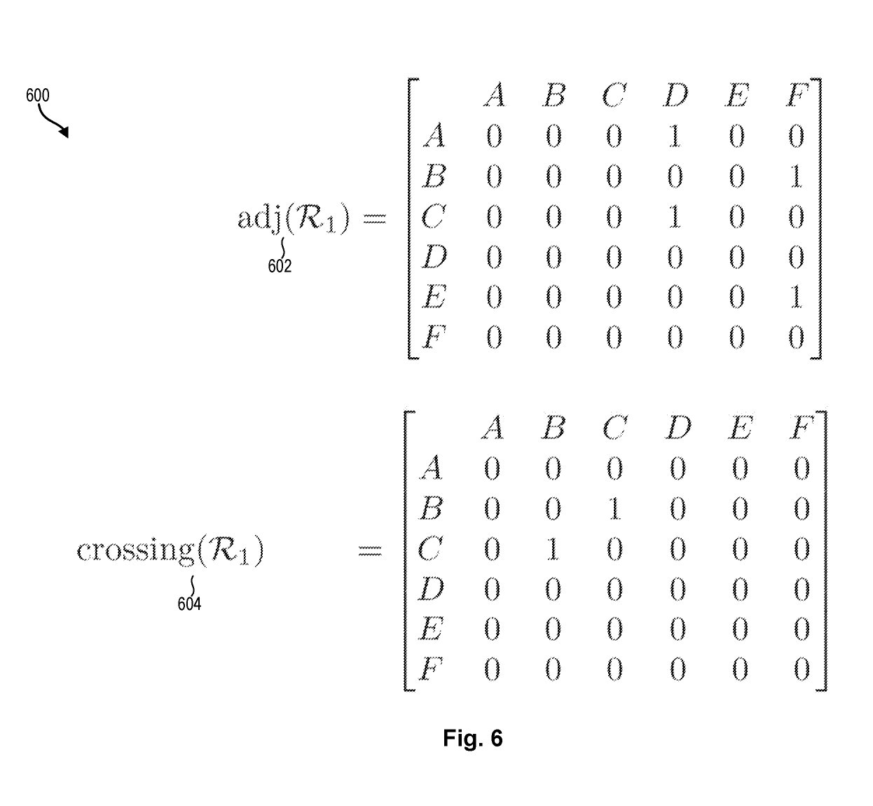

Referring now to FIG. 6, for example, various matrices 600 may be created to identify scenario features associated with the road network 400 depicted by FIG. 4. In one embodiment, for example, an adjacency matrix 602 may be used to identify areas where one pathway A-F feeds into another pathway A-F, while a crossing matrix 604 may be used to identify areas where one pathway A-F crosses another pathway A-F. As shown, an entry in the adjacency matrix 602 of “1” indicates that an edge of one pathway A-F goes into an edge of another pathway A-F, while an entry of “0” indicates no directed connection between pathways A-F. Similarly, an entry of “1” in the crossing matrix 604 indicates that one pathway A-F crosses another pathway A-F. An entry of “0” in the crossing matrix 604 indicates no intersection between pathways A-F.

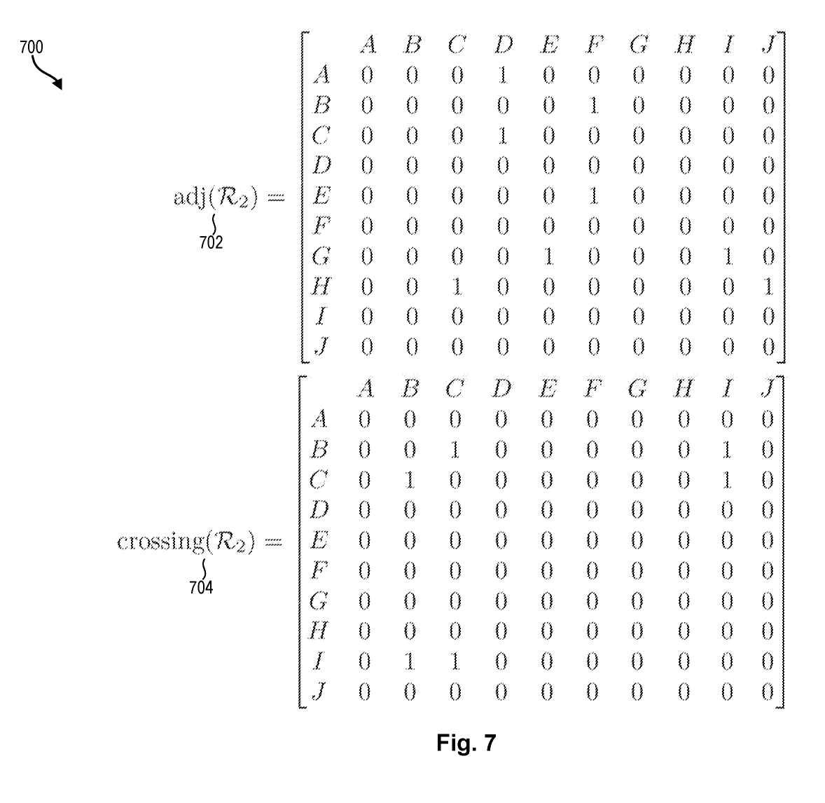

Referring now to FIG. 7, equivalent matrices 700 (specifically, an adjacency matrix 702 and a crossing matrix 704) may be created to identify scenario features corresponding to the road network 500 illustrated by FIG. 5. The matrices 600, 700 of FIGS. 6 and 7 may be compared to determine whether the road network 400 of FIG. 4 is the “same as,” or equivalent to, the road network 500 of FIG. 5. That is, the road networks 400, of FIGS. 4 and 5 may be deemed equivalent if the connectivity and crossings are the same, even though the road networks 400, 500 may be located in different geographic locations and/or labeled differently.

In one embodiment, isometric equivalence for a given or reference road network [symbol] _{ref} may be determined by:

$${ℱ}_{iso} ( ℛ , {ℛ}_{ref} ) = \{ \begin{matrix} & if there exists a permutation matrix \\ 1 , & P such that Padj ( ℛ ) {P}^{T} = adj ( {ℛ}_{ref} ) and \\ & P such that P crossing ( ℛ ) {P}^{T} = crossing ( {ℛ}_{ref} ) , \\ 0 , & otherwise ,\end{matrix}$$

In this manner, a scenario feature corresponding to a reference road network may be isolated and analyzed such that a “matching” or substantially equivalent road network may be identified.

In another embodiment, a scenario feature corresponding to a given or reference road network may be analyzed to determine whether another road network “contains” the reference road network. This analysis may be represented by:

$${ℱ}_{con} ( ℛ , {ℛ}_{ref} ) = \{ \begin{matrix} & if there exists a permutation matrix \\ 1 , & P such that Padj ( {ℛ}_{part} ) {P}^{T} = adj ( {ℛ}_{ref} ) and \\ & P such that P crossing ( {ℛ}_{part} ) {P}^{T} = crossing ( {ℛ}_{ref} ) , \\ 0 , & otherwise ,\end{matrix}$$

where [symbol] ₚₐᵣₜ is [symbol] with the same-numbered rows and columns deleted.

As previously discussed, the road network 400 of FIG. 4 may be defined by the adjacency matrix 602 and crossing matrix 604 of FIG. 6. If the pathway labels A-F were re-ordered to form a second road network [symbol] ₁*, the road network 400 would not function differently, although in general adj( [symbol] ₁)≠adj( [symbol] ₁*) and crossing( [symbol] ₁)≠crossing( [symbol] ₁*). Similarly, if the road networks were located in different areas, or oriented differently, they may not be the self-same road network 400. However, [symbol] ᵢₛₒ( [symbol] ₁, [symbol] ₁*)=1, which indicates that [symbol] ₁ and [symbol] ₁* may be in some sense the same.

By inspection, the road network 400 of FIG. 4 may be considered to be part of, or contained in, the road network 500 of FIG. 5. It is thus reasonable to expect anything dangerous about the road network 400 of FIG. 4 may also affect the safety of the road network 500 of FIG. 5. Beneficially, therefore, some embodiments may identify one road network 400 as being contained in another road network 500.

As discussed above, the adjacency matrix 702 and crossing matrix 704 for the second road network 500 ( [symbol] ₂) are illustrated in FIG. 7. By inspection, it can be seen that eliminating rows and columns G-J gives the same adjacency 602 and crossing matrices 604 as the first road network 400 ( [symbol] ₁), as illustrated in FIG. 6. Thus, [symbol] _{con}( [symbol] ₁, [symbol] ₂)=1.

In certain embodiments, a large library of reference road networks may create a large number of features and [symbol] ᵢₛₒ and [symbol] _{con}. Given road networks reference [symbol] _{ref,1}, [symbol] _{ref,2} . . . [symbol] _{ref,p}, and a road network [symbol] to be evaluated, various scenario features may be identified:

$$F ( ℛ ) = [ \begin{matrix}{ℱ}_{iso} ( ℛ , {ℛ}_{ref , 1} ) \\ ⋮ \\ {ℱ}_{iso} ( ℛ , {ℛ}_{ref , p} ) \\ {ℱ}_{con} ( ℛ , {ℛ}_{ref , 1} ) \\ ⋮ \\ {ℱ}_{iso} ( ℛ , {ℛ}_{ref , p} ) \\ ⋮\end{matrix} ]$$

In certain embodiments, such a vector of scenario features may be used in accordance with embodiments of methods 200, 300 for identifying and generating high-value test scenarios for autonomous vehicles, previously described with reference to FIGS. 2 and 3 above.

In the above disclosure, reference has been made to the accompanying drawings, which form a part hereof, and in which is shown by way of illustration specific implementations in which the disclosure may be practiced. It is understood that other implementations may be utilized and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

While various embodiments of the present disclosure have been described above, it should be understood that they have been presented by way of example only, and not limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments, but should be defined only in accordance with the following claims and their equivalents. The foregoing description has been presented for the purposes of illustration and description. It is not intended to be exhaustive or to limit the disclosure to the precise form disclosed. Many modifications and variations are possible in light of the above teaching. Further, it should be noted that any or all of the aforementioned alternate implementations may be used in any combination desired to form additional hybrid implementations of the disclosure.

1. A method for generating high-value test scenarios for autonomous vehicles, comprising:
identifying a plurality of scenarios, each of the plurality of scenarios associated with a location on a road network;
determining an injury value for each of the plurality of scenarios;
storing each of the plurality of scenarios and their associated injury values in a database;
selecting a desired location for testing an autonomous vehicle;
identifying, in the database, at least one of the plurality of scenarios associated with the desired location and having an associated injury value that exceeds a predetermined threshold; and
generating a virtual reality test environment for the autonomous vehicle based on the at least one scenario.

2. The method of claim 1, wherein determining an injury value comprises extracting a measured injury value from an incident corresponding to the scenario.

3. The method of claim 1, wherein determining an injury value comprises determining an expected injury value as a function of an estimator parameter value and at least one feature value, the at least one feature value corresponding to a feature of a hypothetical scenario.

4. The method of claim 3, further comprising manipulating the at least one feature value to increase the expected injury value.

5. The method of claim 3, wherein the at least one feature is selected from the group consisting of the location, a time of day, weather, precipitation, a traffic flow, configuration of road network users, a vehicle speed, and a vehicle action.

6. The method of claim 1, further comprising analogizing, based on at least one feature, a first road network of a first scenario to a second road network of a second scenario.

7. The method of claim 6, wherein analogizing further comprises one of determining that the second road network contains the first road network, and determining that the second road network is isometrically equivalent to the first road network.

8. The method of claim 1, wherein the injury value comprises a real number greater than or equal to zero.

9. The method of claim 1, further comprising determining at least one initial condition corresponding to each of the plurality of scenarios.

10. The method of claim 9, wherein the at least one initial condition is selected from the group consisting of an initial position, an initial velocity, and an initial physical state of the autonomous vehicle.

11. A system for generating high-value test scenarios for autonomous vehicles, comprising:
at least one autonomous vehicle;
at least one processor; and
at least one memory device operably coupled to the at least one processor and storing instructions for execution on the at least one processor, the instructions causing the at least one processor to:
identify a plurality of scenarios, each of the plurality of scenarios associated with a location on a road network;
determine an injury value for each of the plurality of scenarios;
store each of the plurality of scenarios and their associated injury values in a database;
select a desired location for testing the at least one autonomous vehicle;
identify, in the database, at least one of the plurality of scenarios associated with the desired location and having an associated injury value that exceeds a predetermined threshold; and
generate a virtual reality test environment for the autonomous vehicle based on the at least one scenario.

12. The system of claim 11, wherein determining an injury value comprises extracting a measured injury value from an incident corresponding to the scenario.

13. The system of claim 11, wherein determining an injury value comprises determining an expected injury value as a function of an estimator parameter value and at least one feature value, the at least one feature value corresponding to a feature of a hypothetical scenario.

14. The system of claim 13, wherein the at least one feature is selected from the group consisting of the location, a time of day, weather, precipitation, a traffic flow, configuration of road network users, a vehicle speed, and a vehicle action.

15. The system of claim 11, the instructions further causing the at least one processor to analogize, based on at least one feature, a first road network associated with a first scenario to a second road network associated with a second scenario.

16. The system of claim 15, wherein analogizing further comprises one of determining that the second road network contains the first road network, and determining that the second road network is isometrically equivalent to the first road network.

17. A computer program product for generating high-value test scenarios for autonomous vehicles, the computer program product comprising a non-transitory computer-readable storage medium having computer-usable program code embodied therein, the computer-usable program code configured to perform the following when executed by at least one processor:
identify a plurality of scenarios, each of the plurality of scenarios associated with a location on a road network;
determine an injury value for each of the plurality of scenarios;
store each of the plurality of scenarios and their associated injury values in a database;
select a desired location for testing the at least one autonomous vehicle;
identify, in the database, at least one of the plurality of scenarios associated with the desired location and having an associated injury value that exceeds a predetermined threshold; and
generate a virtual reality test environment for the autonomous vehicle based on the at least one scenario.

18. The computer program product of claim 17, wherein determining an injury value comprises extracting a measured injury value from an incident corresponding to the scenario.

19. The computer program product of claim 17, wherein determining an injury value comprises determining an expected injury value as a function of an estimator parameter value and at least one feature value, the at least one feature value corresponding to a feature of a hypothetical scenario.

20. The computer program product of claim 17, the computer-usable program code further configured to analogize, based on at least one feature, a first road network of a first scenario to a second road network of a second scenario.
